(19) United States
(12) Patent Application Publication
(10) Pub. No.: US 2020/0071816 A1
(43) Pub. Date: Mar. 5, 2020

(54) METHODS FOR SELECTIVE DEPOSITION USING MOLYBDENUM HEXACARBONYL

(71) Applicant: APPLIED MATERIALS, INC., Santa Clara, CA (US)

(72) Inventors: Wei LEI, Campbell, CA (US); Jeffrey ANTHIS, Redwood City, CA (US)

(21) Appl. No.: 16/557,086

(22) Filed: Aug. 30, 2019

Related U.S. Application Data
(60) Provisional application No. 62/726,135, filed on Aug. 31, 2018.

(51) Int. Cl. C23C 16/16; C23C 16/08; C23C 16/02; C23C 16/44

(52) U.S. Cl. CPC C23C 16/16; C23C 16/4404; C23C 16/0236; C23C 16/08

(57) ABSTRACT

Methods for selectively depositing a layer atop a substrate having a metal surface and a dielectric surface are provided including contacting the substrate and metal surface with molybdenum hexacarbonyl to selectively deposit a molybdenum layer atop the metal surface of the substrate, wherein the dielectric layer inhibits deposition of the molybdenum layer atop the dielectric surface. In embodiments, contacting the substrate and metal surface with molybdenum hexacarbonyl is performed at a low temperature such as below 150 degrees Celsius or about 105 to about 125 degrees Celsius.

### CROSS-REFERENCE TO RELATED APPLICATIONS

This application claims benefit of U.S. provisional patent application Ser. No. 62/726,135, filed Aug. 31, 2018 herein incorporated by reference in its entirety.

### FIELD

Embodiments of the present disclosure generally relate to methods for selective deposition using molybdenum hexacarbonyl.

### BACKGROUND

Selective deposition processes can advantageously reduce the number of steps and cost involved in conventional lithography while keeping up with the pace of device dimension shrinkage. Selective deposition in a metal dielectric pattern is of high potential value in both middle end of line (MEOL) and back-end of line (BEOL) applications. Some alternative selective metal deposition techniques have emerged, such as selective tungsten, and selective ruthenium. However, none of these alternative techniques provide a complete metal-organic precursor based molybdenum solution due to limitations relating to precursor selection and reaction conditions. The inventors have observed advantages in precursor selection including the presence of one or more function groups and/or reaction conditions including the use of carbonyl function group and the effect of low process temperature. Because the method of the present disclosure uses halide free metal-organic chemical and also uses low temperature process, it can be used in application where substrate is sensitive to chemical and (or) thermal damage.

Accordingly, the inventors have developed improved methods for selective deposition using molybdenum formed from molybdenum hexacarbonyl.

### SUMMARY

Methods and apparatus for selective deposition are provided herein. In some embodiments, a method of selectively depositing a layer atop a substrate having a metal surface and a dielectric surface, includes: contacting the metal surface with molybdenum hexacarbonyl to selectively deposit a molybdenum layer atop the metal surface of the substrate, wherein the dielectric surface inhibits deposition of the molybdenum layer atop the dielectric surface, wherein contacting the metal surface with molybdenum hexacarbonyl is performed at a first temperature of 150 degrees Celsius or less to thermally decompose the molybdenum hexacarbonyl. In embodiments, contacting the metal surface with molybdenum hexacarbonyl is performed at a first temperature of about 105 to about 125 degrees Celsius.

In some embodiments, a method of selectively depositing a layer atop a substrate having a metal surface and a dielectric surface, includes: contacting a substrate comprising a metal surface and a dielectric layer atop the metal surface with molybdenum hexacarbonyl to selectively deposit a molybdenum layer atop the metal surface of the substrate, wherein the dielectric layer comprises a feature disposed atop the metal surface, and wherein the feature has a top and a bottom and the bottom of the feature is in fluid communication with the metal surface, wherein contacting the substrate with molybdenum hexacarbonyl is performed at a first temperature of 150 degrees Celsius or less to thermally decompose the molybdenum hexacarbonyl.

In some embodiments, a method of depositing a layer atop a substrate having a metal surface and a dielectric surface, includes: contacting a substrate comprising a metal surface and a dielectric surface comprising a feature in fluid communication with the metal surface with molybdenum hexacarbonyl to form a molybdenum layer atop the metal surface of the substrate, and within the feature, wherein the molybdenum hexacarbonyl is selective towards the metal surface, wherein contacting the substrate with molybdenum hexacarbonyl is performed at a first temperature of 150 degrees Celsius or less to thermally decompose the molybdenum hexacarbonyl.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a process chamber suitable for performing a thermal deposition process in accordance with some embodiments of the present disclosure.

FIG. 2 is a flowchart of a method of selective deposition in accordance with some embodiments of the present disclosure.

FIGS. 3A-3C are illustrative cross-sectional views of the substrate during different stages of the processing sequence of FIG. 2 in accordance with some embodiments of the present disclosure.

FIG. 4 is a flow diagram of a method of selective deposition in accordance with some embodiments of the present disclosure.

FIGS. 5A-5C are illustrative cross-sectional views of the substrate during different stages of the processing sequence of FIG. 4 in accordance with some embodiments of the present disclosure.

FIG. 6 is a flow diagram of a method of depositing a layer atop a substrate having a metal surface and a dielectric surface.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods for selective deposition using molybdenum (0) precursors such as molybdenum hexacarbonyl are provided herein. In some embodiments, the methods described herein advantageously select carbonyl precursors without reactive or corrosive chemical species such as chlorine, or high temperatures dissociation temperatures e.g. greater than 130 degrees Celsius.

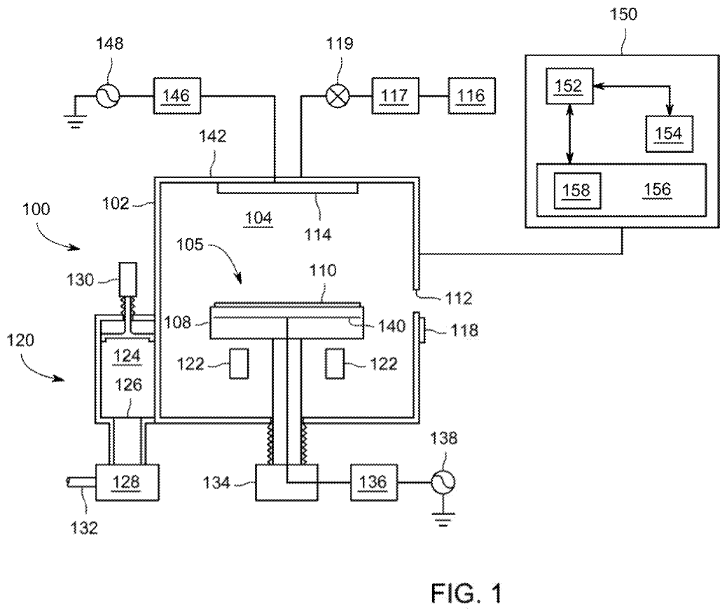

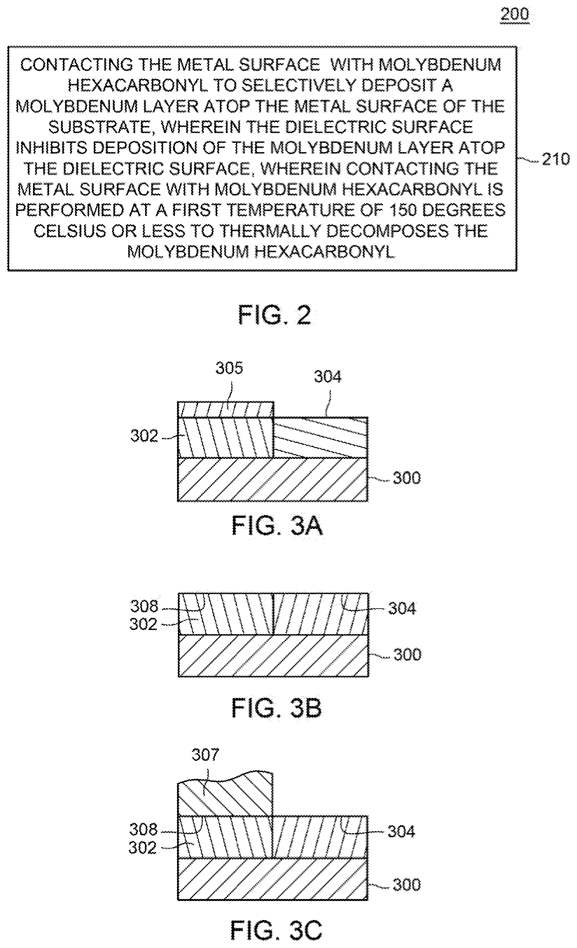

FIG. 2 is a flow diagram of a method 200 of processing a substrate having a metal surface and a dielectric surface in accordance with some embodiments of the present disclosure. FIGS. 3A-3C are illustrative cross-sectional views of the substrate during different stages of the processing sequence of FIG. 2 in accordance with some embodiments of the present disclosure. The methods of the present disclosure may be performed in process chambers configured for thermal deposition techniques such as atomic layer deposition (ALD) or chemical vapor deposition (CVD), or the process chamber discussed below with respect to FIG. 1.

The method 200 is performed on a substrate 300, as depicted in FIG. 3A, having a metal surface 302 and a dielectric surface 304. In embodiments, substrate 300 may comprise a material such as crystalline silicon (e.g., Si<100> or Si<111>), silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. In embodiments, the substrate 300 may have various dimensions, such as 200 mm, 300 mm, 450 mm or other diameters for round substrates. The substrate 300 may also be any polygonal, square, rectangular, curved or otherwise non-circular workpiece, such as a polygonal glass substrate used in the fabrication of flat panel displays. Unless otherwise noted, implementations and examples described herein are conducted on substrates such as substrate 300 with a 200 mm diameter, a 300 mm diameter, or a 450 mm diameter substrate.

In embodiments, dielectric surface 304 is not the same as metal surface 302. In some embodiments, the dielectric surface 304 is deposited via any suitable atomic layer deposition process or a chemical layer deposition process. In some embodiments, the dielectric surface 304 may comprise a low-k dielectric layer deposited atop substrate 300. In some embodiments, dielectric surface 304 may include any low-k dielectric material suitable for semiconductor device fabrication. Non-limiting materials suitable as low-k dielectric material may comprise a silicon containing material, for example, such as silicon oxide (SiO2), silicon nitride, or silicon oxynitride (SiON). In embodiments, the low-k dielectric material may have a low-k value of less than about 3.9 (for example, about 2.5 to about 3.5). In some embodiments, the dielectric surface 304 may comprise hafnium oxide such as HfOₓ.

In some embodiments, metal surface 302 is deposited via any suitable atomic layer deposition process or a chemical layer deposition process. In some embodiments, the metal surface 302 may comprise any metal suitable for semiconductor device fabrication. Non-limiting metal suitable for metal surface 302 comprise copper (Cu), cobalt (Co), tungsten (W), niobium (Nb), ruthenium (Ru), aluminum (Al), titanium (Ti), nickel (Ni), vanadium (V), zirconium (Zr), Iron (Fe), and combinations thereof such as alloys and the like. Referring to FIG. 3A, a metal oxide layer 305 is shown disposed atop metal surface 302. Metal oxide layer 305 may be a native oxide layer or form as metal surface 302 contacts oxygen, for example in air or water. In some embodiments, metal oxide layer 305 may be problematic in that the metal oxide layer 305 may be less conductive than an exposed metal layer and be less selective towards selective molybdenum deposition in accordance with the present disclosure. In some embodiments, the metal oxide layer 305 is removed prior to depositing a molybdenum layer atop, or directly atop metal surface 302 to form an exposed metal surface. Non-limiting examples of exposed metal surface material includes substantially pure, for example, substantially free of oxide, copper (Cu), cobalt (Co), tungsten (W), niobium (Nb), ruthenium (Ru), aluminum (Al), titanium (Ti), nickel (Ni), vanadium (V), zirconium (Zr), and combinations thereof such as alloys and the like. In one embodiment, exposed metal surface is cobalt, or substantially pure cobalt.

In accordance with the present disclosure, the method 200 begins at 210 and as depicted in FIGS. 3B and 3C, by contacting the metal surface 302 and top surface 308 with one or more molybdenum (0) precursors such as (bicyclo-hepta-diene)tetracarbonyl molybdenum, molybdenum hexacarbonyl, and combinations thereof to selectively deposit a molybdenum layer atop the metal surface 302 and top surface 308 of the substrate, wherein the dielectric surface 304 inhibits deposition of the molybdenum layer atop the dielectric surface 304.

In embodiments, the one or more molybdenum (0) precursors such as (bicyclo-hepta-diene)tetracarbonyl molybdenum, or molybdenum hexacarbonyl contact metal surface 302 in an amount sufficient to deposit a molybdenum layer 307 on metal surface 302. For example, the one or more molybdenum (0) precursors such as molybdenum hexacarbonyl may thermally decompose in the process chamber and form a layer upon metal surface 302. In embodiments, contacting the metal surface 302 with one or more molybdenum (0) precursors such as molybdenum hexacarbonyl is performed using an amount of the one or more molybdenum (0) precursors such as molybdenum hexacarbonyl sufficient to form molybdenum layer 307, under conditions suitable for the reaction such as a thermal decomposition reaction of the one or more molybdenum (0) precursors. In embodiments, contacting the metal surface 302 with one or more molybdenum (0) precursors such as molybdenum hexacarbonyl is performed at a first temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In embodiments, the substrate 300 is maintained at a temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In one embodiment, the first temperature is 150 degrees Celsius or less than 150 degrees Celsius. In embodiments, contacting the metal surface 302 with one or more molybdenum (0) precursors such as molybdenum hexacarbonyl is performed at a pressure in an amount of 1 to 15 Torr, about 1 to about 5 Torr, about 4 Torr, about 3 Torr, or 3 Torr. In embodiments, contacting the metal surface 302 with one or more molybdenum (0) precursors such as molybdenum hexacarbonyl is performed for about 3 to about 20 minutes, such as about 5 minutes to about 10 minutes. Non-limiting examples of molybdenum (0) precursors include (bicyclo-hepta-diene)tetracarbonyl molybdenum, molybdenum hexacarbonyl (Mo(Co)₆), and combinations thereof. In embodiments, molybdenum (0) precursors include molybdenum compositions having an oxidation state of zero. In embodiments, molybdenum (0) precursors include molybdenum compositions having carbon monoxide as a ligand.

In some embodiments, molybdenum hexacarbonyl contacts metal surface 302, or thermally decomposes to contact metal surface 302 in an amount sufficient to deposit a molybdenum layer 307 on metal surface 302. For example, molybdenum hexacarbonyl may thermally decompose in the process chamber and form a molybdenum layer upon metal surface 302. In embodiments, contacting the metal surface 302 with molybdenum hexacarbonyl is performed using an amount of molybdenum hexacarbonyl sufficient to form molybdenum layer 307, under conditions suitable for the reaction. In embodiments, contacting the metal surface 302 with molybdenum hexacarbonyl is performed using an amount of molybdenum hexacarbonyl sufficient to form molybdenum layer 307 having a thickness of 20 angstroms to 1000 angstrom, 20 to 100 angstroms, greater than 20 angstroms, or greater than 100 angstroms. In embodiments, contacting the metal surface 302 with molybdenum hexacarbonyl or thermally decomposed constituents thereof is performed at a first temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In one embodiment, the first temperature is 150 degrees Celsius or less than 150 degrees Celsius. In embodiments, contacting the metal surface 302 with molybdenum hexacarbonyl or decomposed constituents thereof is performed at a pressure in an amount of 1 to 15 Torr, about 1 to about 5 Torr, about 4 Torr, about 3 Torr, or 3 Torr. In embodiments, contacting the metal surface 302 with molybdenum hexacarbonyl or decomposed constituents thereof is performed for about 3 to about 20 minutes, such as about 5 minutes to about 10 minutes.

In embodiments, contacting the metal surface 302 with one or more molybdenum (0) precursors such as molybdenum hexacarbonyl is performed under vacuum, such that oxygen is not available to inhibit the reaction or promote the growth of additional metal oxide material atop metal surface 302. In embodiments, contacting the metal surface 302 with one or more molybdenum (0) precursors such as molybdenum hexacarbonyl is performed in a chamber such as the process chamber of FIG. 1. The process chamber of FIG. 1 may be an oxygen-free chamber.

In some embodiments, one or more molybdenum (0) precursors such as molybdenum hexacarbonyl is provided in a vapor or gas precursor form and may include for example a concentration of molybdenum (0) precursors such as molybdenum hexacarbonyl sufficient to form a monolayer upon metal surface 302, or, in embodiments, a layer having a thickness of greater than 20 angstroms. In embodiments, the substrate 300 having a metal surface 302 and a dielectric surface 304 is contacted with a gaseous precursor material comprising molybdenum (0) precursors such as molybdenum hexacarbonyl for about 3 minutes to about 3 hours to form the molybdenum layer 307. The molybdenum (0) precursors such as molybdenum hexacarbonyl including molybdenum molecules have a chemical affinity (e.g. are reactive and selective) to the metal surface 302 and top surface 308. Thus, in some embodiments, the molybdenum layer 307 will only form on the metal surface 302 but not on the dielectric surface 304. In embodiments, the substrate 300 stays or remains under vacuum, after depositing the molybdenum layer 307 to remove any unabsorbed molybdenum molecules or by products from the thermal degradation of molybdenum (0) precursors such as molybdenum hexacarbonyl.

Next, as depicted in FIG. 3C, selectively depositing a molybdenum layer 307 atop the metal surface 302 of the substrate 300 is shown, wherein the dielectric surface 304 inhibits or prevents deposition of the molybdenum layer 307 atop the dielectric surface 304. In some embodiments, the molybdenum layer 307 is deposited via any suitable thermal decomposition reaction, atomic layer deposition process or a chemical layer deposition process. In one embodiments, the molybdenum layer 307 is deposited via a thermal decomposition reaction where molybdenum (0) precursors like molybdenum hexacarbonyl, under low heat conditions such as about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius, dissociate in a process chamber to form chemical constituents such as molybdenum having an affinity towards metal surface 302 over dielectric surface 304.

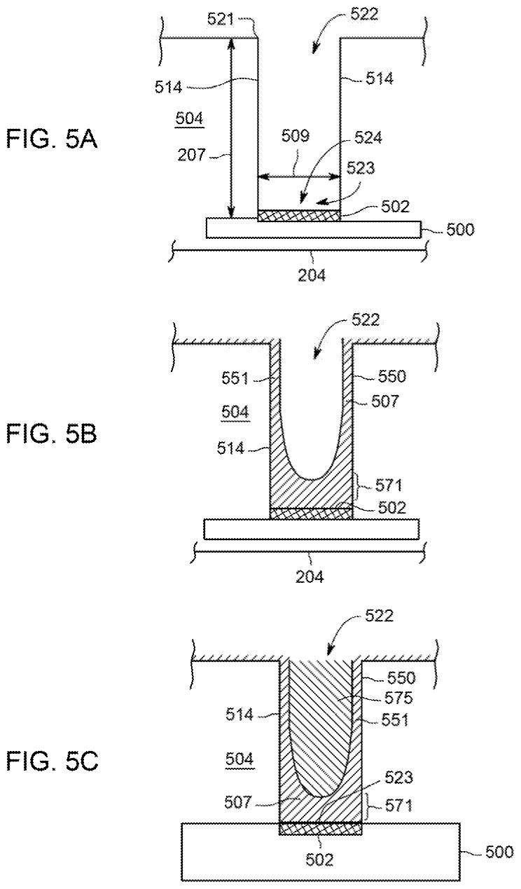

Following the addition of the molybdenum layer 307 the method 200 ends and the substrate may undergo further processing as necessary for completion of a semiconductor device, such as a field effect transistor (FET), a fin field effect transistor (FinFET), a flash memory device, a 3D FINFET device, or the like. For example, other metals such as copper (Cu), cobalt (Co), tungsten (W), niobium (Nb), ruthenium (Ru), and combinations thereof such as alloys, or oxides thereof may be further deposited upon, or directly upon molybdenum layer 307. In one embodiment, metal surface 302 may be copper (Cu), cobalt (Co), tungsten (W), niobium (Nb), ruthenium (Ru) having a molybdenum layer deposited atop or directly atop and in contact with the metal surface 302, and an additional metal layer such as copper (Cu), cobalt (Co), tungsten (W), niobium (Nb), ruthenium (Ru) may be deposited on or directly atop the molybdenum layer. In one embodiment, metal surface 302 may be cobalt (Co) having a molybdenum layer deposited atop or directly atop and in contact with the metal surface 302, and an additional metal layer comprising ruthenium (Ru) may be deposited on or directly atop molybdenum layer. Non-limiting examples of these embodiments are described further below with respect to FIGS. 5A-5C.

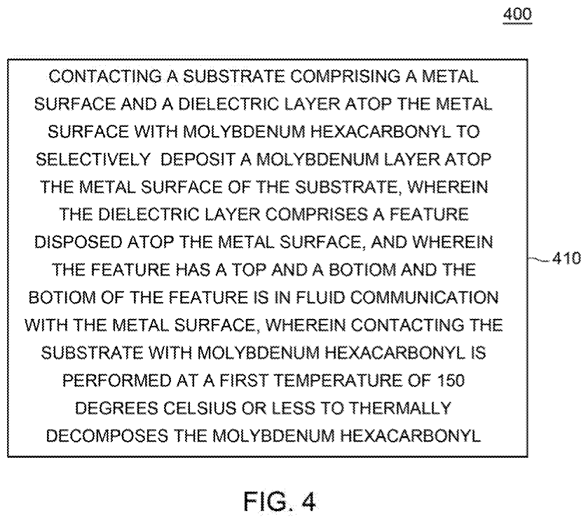

FIG. 4 depicts is a flow diagram of another embodiment of a method of selectively depositing a layer atop a substrate having a metal surface and a dielectric surface in accordance with the present disclosure. FIGS. 5A-5C are illustrative cross-sectional views of the substrate during different stages of the processing sequence of FIG. 4 in accordance with some embodiments of the present disclosure. In embodiments, the methods may be performed in process chambers configured for thermal deposition techniques such as atomic layer deposition (ALD) or chemical vapor deposition (CVD), or the process chamber discussed below with respect to FIG. 1. In embodiments, the methods include contacting a substrate 500 including a metal surface 502 and a dielectric layer 504 atop the metal surface 502 with molybdenum hexacarbonyl to selectively deposit a molybdenum layer atop the metal surface 502 of the substrate 500, wherein the dielectric layer 504 comprises one or more features 550 disposed atop the metal surface 502, and wherein each feature 550 has a top 522 and a bottom 523 and the bottom 523 of one or more features 550 has an opening 524 or is in fluid communication with the metal surface 502.

The method 400 is performed on a substrate 500, as depicted in FIG. 5A, having a metal surface 502 and a dielectric layer 504. In embodiments, substrate 500 may comprise a material such as those described above with respect to substrate 300 including crystalline silicon (e.g., Si<100> or Si<111>), silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. In embodiments, the substrate 500 may have various dimensions, such as those described above with respect to substrate 300.

In some embodiments, metal surface 502 is deposited via any suitable atomic layer deposition process or a chemical layer deposition process. In some embodiments, the metal surface 502 may include any metal suitable for semiconductor device fabrication. Non-limiting metal suitable for metal surface 502 comprise copper (Cu), cobalt (Co), tungsten (W), niobium (Nb), or ruthenium (Ru), and combinations thereof such as alloys and the like such as oxides thereof. Referring to FIG. 5A, a metal oxide layer (not shown) may be disposed atop metal surface 502. Metal oxide layer may be a native oxide layer or form as metal surface 502 contacts oxygen, for example in air or water. In some embodiments, metal oxide layer may be problematic in that the metal oxide layer may be less conductive than an exposed metal layer and be less selective towards selective molybdenum deposition in accordance with the present disclosure. In some embodiments, method include, pre-treating the metal surface 502 to form an exposed metal surface. In some embodiments methods include contacting the metal surface with one or more metal halides to form an exposed metal surface. In some embodiments, the metal oxide layer is removed prior to depositing a molybdenum layer atop, or directly atop metal surface 502 to form an exposed metal surface. Non-limiting examples of exposed metal surface material includes substantially pure, for example, substantially free of oxide, copper (Cu), cobalt (Co), tungsten (W), niobium (Nb), ruthenium (Ru), and combinations thereof such as alloys and the like.

In embodiments, dielectric layer 504 is not the same as metal surface 502. In some embodiments, the dielectric layer 504 is deposited via any suitable atomic layer deposition process or a chemical layer deposition process. In some embodiments, the dielectric layer 504 may comprise a low-k dielectric layer deposited atop substrate 500. In some embodiments, dielectric layer 504 may include any low-k dielectric material suitable for semiconductor device fabrication, and combinations thereof. Non-limiting materials suitable as low-k dielectric material may comprise a silicon containing material, for example, such as silicon oxide (SiO2), silicon nitride, or silicon oxynitride (SiON), or combinations thereof, or combinations of layers thereof. In embodiments, the low-k dielectric material may have a low-k value of less than about 3.9 (for example, about 2.5 to about 3.5). In some embodiments, the dielectric layer 504 may comprise hafnium oxide such as HfOₓ, wherein X is a number such as an integer.

In embodiments, the dielectric layer 504 may include one or more features 550 such as a via or trench formed in the dielectric layer 504. The one or more features 550 may be formed by etching the dielectric layer 504 using any suitable etch process. In some embodiments, the one or more features 550 is defined by one or more sidewalls 514, an opening and upper corners 521. In some embodiments, the one or more features 550 may have a high aspect ratio, e.g., an aspect ratio between about of about 5:1 and about 20:1. As used herein, the aspect ratio is the ratio of a depth of the feature to a width of the feature. In embodiments, the one or more features 550 has a width 509 less than or equal to 20 nanometers, less than or equal to 10 nanometers, or a width 509 between 5 to 10 nanometers.

In accordance with the present disclosure, the method 400 begins at 410 and as depicted in FIGS. 5A and 5B, by contacting the metal surface 502 with one or more molybdenum (0) precursors such as molybdenum hexacarbonyl to selectively deposit a molybdenum layer atop the metal surface 502 of the substrate, wherein the dielectric layer 504 inhibits the deposition of the molybdenum layer atop the dielectric layer 504. In embodiments, contacting the substrate with molybdenum hexacarbonyl is performed at a first temperature of 150 degrees Celsius or less to thermally decomposes the molybdenum hexacarbonyl. In some embodiments, the first temperature is obtained by heating the substrate to 150 degrees Celsius or less to thermally decompose the molybdenum hexacarbonyl into molybdenum and dissociation products or by-products. In some embodiments, the first temperature is obtained by heating molybdenum hexacarbonyl to 150 degrees Celsius or less to thermally decompose the molybdenum hexacarbonyl into molybdenum and dissociation products or by-products. In one embodiment, the reaction conditions promote thermal degradation of the molybdenum hexacarbonyl, and the reaction is devoid of other deposition techniques including photo-assisted metal atomic layer deposition or photo-assisted chemical vapor deposition.

In embodiments, the one or more molybdenum (0) precursors such as molybdenum hexacarbonyl contact metal surface 502 in an amount sufficient to deposit a molybdenum layer 507 on metal surface 502. For example, the one or more molybdenum (0) precursors such as molybdenum hexacarbonyl may thermally decompose in the process chamber and form a layer upon metal surface 502. In embodiments, contacting the metal surface 502 with one or more molybdenum (0) precursors such as molybdenum hexacarbonyl is performed using an amount of the one or more molybdenum (0) precursors such as molybdenum hexacarbonyl sufficient to form molybdenum layer 507, under conditions suitable for the reaction. In embodiments, contacting the metal surface 502 with one or more molybdenum (0) precursors such as molybdenum hexacarbonyl is performed using an amount of the one or more molybdenum (0) precursors such as molybdenum hexacarbonyl sufficient to form molybdenum layer 507 having a thickness of greater than 20 angstroms, or thickness suitable to partially or completely fill one or more features 550. In embodiments, contacting the metal surface 502 with one or more molybdenum (0) precursors such as molybdenum hexacarbonyl is performed at a first temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In one embodiment, the first temperature is 150 degrees Celsius or less than 150 degrees Celsius. In embodiments, contacting the metal surface 502 with one or more molybdenum (0) precursors such as molybdenum hexacarbonyl is performed at a pressure in an amount of 1 to 15 Torr, about 1 to about 5 Torr, about 4 Torr, about 3 Torr, or 3 Torr. In embodiments, contacting the metal surface 502 with one or more molybdenum (0) precursors such as molybdenum hexacarbonyl is performed for about 3 to about 20 minutes, such as about 5 minutes to about 10 minutes. Non-limiting examples of molybdenum (0) precursors include (bicyclo-hepta-diene)tetracarbonyl molybdenum, molybdenum hexacarbonyl (Mo(Co)₆), and combinations thereof.

In some embodiments, (bicyclo-hepta-diene)tetracarbonyl molybdenum or molybdenum hexacarbonyl contacts a metal surface 502 in an amount sufficient to deposit a molybdenum layer 507 on metal surface 302 and fill one or more features 550. For example, molybdenum hexacarbonyl may thermally decompose in the process chamber and form a layer upon metal surface 502 and within one or more features 550. In embodiments, contacting the metal surface 502 and filling one or more features 550 with molybdenum is performed using an amount of molybdenum hexacarbonyl sufficient to form molybdenum layer 507, under conditions suitable for the reaction. In embodiments, contacting the metal surface 502 with molybdenum hexacarbonyl is performed at a first temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In embodiments, substrate 500 is maintained at a temperature of about 105 to about 125 degrees Celsius, or about 110 to about 120 degrees Celsius, or about 111 degrees Celsius, about 112 degrees Celsius, about 113 degrees Celsius, about 114 degrees Celsius, about 115 degrees Celsius, about 116 degrees Celsius, about 117 degrees Celsius. In embodiments, contacting the metal surface 502 with molybdenum hexacarbonyl is performed at a pressure in an amount of 1 to 15 Torr, about 1 to about 5 Torr, about 4 Torr, about 3 Torr, or 3 Torr. In embodiments, contacting the metal surface 302 with molybdenum hexacarbonyl is performed for about 3 to about 20 minutes, such as about 5 minutes to about 10 minutes.

In embodiments, contacting the metal surface 502 with one or more molybdenum (0) precursors such as molybdenum hexacarbonyl is performed under vacuum, such that oxygen is not available to inhibit the reaction or promote the growth of additional metal oxide material atop metal surface 502. In embodiments, contacting the metal surface 502 with one or more molybdenum (0) precursors such as molybdenum hexacarbonyl is performed in a chamber such as the process chamber of FIG. 1. The process chamber of FIG. 1 may be oxygen-free.

In some embodiments, one or more molybdenum (0) precursors such as molybdenum hexacarbonyl is provided in a vapor or gas precursor form and may include for example a concentration of molybdenum (0) precursors such as molybdenum hexacarbonyl sufficient to form a monolayer upon metal surface 502 and within one or more features 550. In embodiments, the substrate 500 having a metal surface 502 and a dielectric layer 504 is contacted with a gaseous precursor material comprising molybdenum (0) precursors such as molybdenum hexacarbonyl for about 3 minutes to about 3 hours to form the molybdenum layer 507. The molybdenum (0) precursors such as molybdenum hexacarbonyl molecules have a chemical affinity (e.g. are reactive and selective) to the metal surface 502. Thus, in some embodiments, the molybdenum layer 507 will form on the metal surface 502 such as a capping layer by forming molybdenum layer 507 within the one or more features 550. In embodiments, the substrate 500 stays or remains under vacuum, after depositing the molybdenum layer 507 to remove any unabsorbed molybdenum molecules or by products from the thermal degradation of molybdenum (0) precursors such as molybdenum hexacarbonyl.

Referring to FIG. 5C, molybdenum layer 507 may be deposited on substrate 500 and within one or more features 550 in a process chamber configured to deposit a layer such as a capping layer 551. The capping layer 551 can be a layer conformably formed along at least a portion of the sidewalls 514 and/or upon the top surface of metal surface 502 disposed in fluid communication with one or more features 550 such as trench or via such that a substantial portion of the one or more features 550 during deposition of the layer fills from the bottom 523 to the top 522 of the one or more features 550. In embodiments the capping layer 551 is the same as molybdenum layer 507. In embodiments, portions or voids within the one or more features 550 remains unfilled after deposition of the molybdenum layer. In some embodiments, the capping layer 551 may be formed along the entirety of the sidewalls 514 and fill a bottom portion 571 of the one or more features 550.

Following the addition of the molybdenum layer 507 such as a capping layer the method 400 ends and the substrate may undergo further processing as necessary for completion of a semiconductor device, such as a field effect transistor (FET), a fin field effect transistor (FinFET), a flash memory device, a 3D FINFET device, or the like. For example, referring now to FIG. 5C other metals such as copper (Cu), cobalt (Co), tungsten (W), niobium (Nb), ruthenium (Ru), aluminum (Al), titanium (Ti), nickel (Ni), vanadium (V), zirconium (Zr), Iron (Fe), such as alloys, or oxides thereof may be further deposited upon, or directly upon molybdenum layer 307 for example, within one or more features 550. In one embodiment, metal surface 502 may be copper (Cu), cobalt (Co), tungsten (W), niobium (Nb), ruthenium (Ru) having a molybdenum layer 507 deposited atop or directly atop and in contact with the metal surface 502, and one or more additional metal layers 575 such as copper (Cu), cobalt (Co), tungsten (W), niobium (Nb), ruthenium (Ru) may be deposited on or directly atop the molybdenum layer 507. In one embodiment, metal surface 502 may be cobalt (Co) having a molybdenum layer 507 deposited atop or directly atop and in contact with the metal surface 502, and one or more additional metal layers 575 comprising ruthenium (Ru) may be deposited on or directly atop molybdenum layer 507 within one or more features 550. In embodiments, the molybdenum layer 507 has a thickness between 20 and 1000 angstroms. In embodiments, the molybdenum layer 507 has a thickness of greater than 20 angstroms.

In one embodiment, metal surface 502 is copper (Cu) having a molybdenum layer 507 deposited atop or directly atop and in contact with the metal surface 502, and one or more additional metal layers 575 comprising ruthenium (Ru) may be deposited on or directly atop molybdenum layer 507 within one or more features 550. In embodiments, the molybdenum layer 507 has a thickness between 20 and 1000 angstroms. In embodiments, the molybdenum layer 507 has a thickness of greater than 20 angstroms.

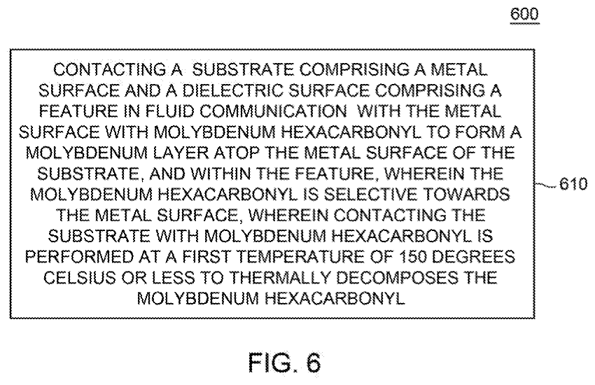

FIG. 6 is a flow diagram of a method of depositing a layer atop a substrate having a metal surface and a dielectric surface in accordance with the present disclosure. Embodiments include at 610, contacting a substrate comprising a metal surface and a dielectric surface comprising a feature in fluid communication with the metal surface with molybdenum hexacarbonyl to form a molybdenum layer atop the metal surface of the substrate, and within the feature, wherein the molybdenum hexacarbonyl is selective towards the metal layer. In embodiments, the method includes filling the feature from a bottom to a top with molybdenum.

FIG. 1 depicts a schematic diagram of an illustrative apparatus of the kind that may be used to practice embodiments of the disclosure as discussed herein. The apparatus 100 may comprise a controller 150 and a process chamber 102 having an exhaust system 120 for removing excess process gases, processing by-products, or the like, from the inner volume 105 of the process chamber 102. Exemplary process chambers may include any of several process chambers configured for thermal decomposition reactions, atomic layer deposition (ALD), or chemical vapor deposition (CVD), available from Applied Materials, Inc. of Santa Clara, Calif. Other suitable process chambers from other manufacturers may similarly be used.

The process chamber 102 has an inner volume 105 that may include a processing volume 104. The processing volume 104 may be defined, for example, between a substrate support 108 disposed within the process chamber 102 for supporting a substrate 110 thereupon during processing and one or more gas inlets, such as a showerhead 114 and/or nozzles provided at predetermined locations. In some embodiments, the substrate support 108 may include a mechanism that retains or supports the substrate 110 on the surface of the substrate support 108, such as an electrostatic chuck, a vacuum chuck, a substrate retaining clamp, or the like (not shown). In some embodiments, the substrate support 108 may include mechanisms for controlling the substrate temperature such as heating and/or cooling devices (not shown), and/or for controlling the species flux and/or ion energy proximate the substrate surface. In embodiments, the process chamber 102 may be an oxygen-free process chamber. In embodiments, substrate support 108 may be include a filament 140, heating mechanism 136 and power source 138 sufficient to heat the substrate and facilitate thermal degradation of the molybdenum precursor in accordance with the present disclosure.

In some embodiments, the substrate support 108 may include an RF bias electrode (not shown). The RF bias electrode may be coupled to one or more bias power sources (one bias power source not shown) through one or more respective matching networks (matching network shown). The one or more bias power sources may be capable of producing up to 1200 W or RF energy at a frequency of about 2 MHz to about 60 MHz, such as at about 2 MHz, or about 13.56 MHz, or about 60 Mhz. In some embodiments, two bias power sources may be provided for coupling RF power through respective matching networks to the RF bias electrode at respective frequencies of about 2 MHz and about 13.56 MHz. The at least one bias power source may provide either continuous or pulsed power. In some embodiments, the bias power source alternatively may be a DC or pulsed DC source.

The substrate 110 may enter the process chamber 102 via an opening 112 in a wall of the process chamber 102. The opening 112 may be selectively sealed via a slit valve 118, or other mechanism for selectively providing access to the interior of the chamber through the opening 112. The substrate support 108 may be coupled to a lift mechanism 134 that may control the position of the substrate support 108 between a lower position (as shown) suitable for transferring substrates into and out of the chamber via the opening 112 and a selectable upper position suitable for processing. The process position may be selected to maximize process uniformity for a particular process. When in at least one of the elevated processing positions, the substrate support 108 may be disposed above the opening 112 to provide a symmetrical processing region.

The one or more gas inlets (e.g., the showerhead 114) may be coupled to a gas supply 116 for providing one or more process gases through a mass flow controller 117 into the processing volume 104 of the process chamber 102. In addition, one or more valves 119 may be provided to control the flow of the one or more process gases. The mass flow controller 117 and one or more valves 119 may be used individually, or in conjunction to provide the process gases at predetermined flow rates at a constant flow rate, or pulsed (as described above).

Although a showerhead 114 is shown in FIG. 1, additional or alternative gas inlets may be provided such as nozzles or inlets disposed in the ceiling or on the sidewalls of the process chamber 102 or at other locations suitable for providing gases to the process chamber 102, such as the base of the process chamber, the periphery of the substrate support, or the like.

The apparatus 100 may utilize capacitively coupled RF energy for plasma processing. For example, the process chamber 102 may have a ceiling 142 made from dielectric materials and a showerhead 114 that is at least partially conductive to provide an RF electrode (or a separate RF electrode may be provided). The showerhead 114 (or other RF electrode) may be coupled to one or more RF power sources (one RF power source 148 shown) through one or more respective matching networks (matching network 146 shown). The one or more plasma sources may be capable of producing up to about 3,000 W, or in some embodiments, up to about 5,000 W, of RF energy at a frequency of about 2 MHz and/or about 13.56 MHz or a high frequency, such as 27 MHz and/or 60 MHz. The exhaust system 120 generally includes a pumping plenum 124 and one or more conduits that couple the pumping plenum 124 to the inner volume 105 (and generally, the processing volume 104) of the process chamber 102.

A vacuum pump 128 may be coupled to the pumping plenum 124 via a pumping port 126 for pumping out the exhaust gases from the process chamber via one or more exhaust ports (two exhaust ports 122 shown). The vacuum pump 128 may be fluidly coupled to an exhaust outlet 132 for routing the exhaust to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

To facilitate control of the process chamber 102 as described above, the controller 150 may be any form of general-purpose computer processor that can be used in an industrial setting for controlling various chambers and sub-processors. The memory, or computer-readable medium, 156 of the CPU 152 may be one or more of readily available memory such as random access memory (RAM), read only memory (ROM), floppy disk, hard disk, or any other form of digital storage, local or remote. The support circuits 154 are coupled to the CPU 152 for supporting the processor in a conventional manner. These circuits include cache, power supplies, clock circuits, input/output circuitry and subsystems, and the like.

The methods disclosed herein may generally be stored in the memory 156 as a software routine 158 that, when executed by the CPU 152, causes the process chamber 102 to perform processes of the present disclosure. The software routine 158 may also be stored and/or executed by a second CPU (not shown) that is remotely located from the hardware being controlled by the CPU 152. Some or all of the method of the present disclosure may also be performed in hardware. As such, the disclosure may be implemented in software and executed using a computer system, in hardware as, e.g., an application specific integrated circuit or other type of hardware implementation, or as a combination of software and hardware. The software routine 158 may be executed after the substrate 110 is positioned on the substrate support 108. The software routine 158, when executed by the CPU 152, transforms the general purpose computer into a specific purpose computer (controller 150) that controls the chamber operation such that the methods disclosed herein are performed.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure.

In some embodiments, the present disclosure relates to process chamber 102 configured for selectively depositing a layer atop a substrate having a metal surface and a dielectric surface. In embodiments, the process chamber 102 is configured for contacting the metal surface with molybdenum hexacarbonyl to selectively deposit a molybdenum layer atop the metal surface of the substrate, wherein the dielectric surface inhibits deposition of the molybdenum layer atop a dielectric surface, wherein contacting the metal surface with molybdenum hexacarbonyl is performed at a first temperature of 150 degrees Celsius or less to thermally decompose the molybdenum hexacarbonyl.

In some embodiments, the present disclosure relates to process chamber 102 configured for selectively depositing a layer atop a substrate having a metal surface and a dielectric surface. In embodiments, the process chamber 102 is configured for contacting a substrate including a metal surface and a dielectric layer atop the metal surface with molybdenum hexacarbonyl to selectively deposit a molybdenum layer atop the metal surface of the substrate, wherein the dielectric layer includes a feature disposed atop the metal surface, and wherein the feature has a top and a bottom and the bottom of the feature is in fluid communication with the metal surface, wherein contacting the substrate with molybdenum hexacarbonyl is performed at a first temperature of 150 degrees Celsius or less to thermally decompose the molybdenum hexacarbonyl.

In some embodiments, the present disclosure relates to process chamber 102 configured for selectively depositing a layer atop a substrate having a metal surface and a dielectric surface. In embodiments, the process chamber 102 is configured for contacting a substrate comprising a metal surface and a dielectric surface comprising a feature in fluid communication with the metal surface with molybdenum hexacarbonyl to form a molybdenum layer atop the metal surface of the substrate, and within the feature, wherein the molybdenum hexacarbonyl is selective towards the metal surface, wherein contacting the substrate with molybdenum hexacarbonyl is performed at a first temperature of 150 degrees Celsius or less to thermally decompose the molybdenum hexacarbonyl.

In some embodiments, the present disclosure relates to a non-transitory computer readable medium having instructions stored thereon that, when executed, cause a process chamber to perform a method of selectively depositing a layer atop a substrate having a metal surface and a dielectric surface including: contacting the metal surface with molybdenum hexacarbonyl to selectively deposit a molybdenum layer atop the metal surface of the substrate, wherein the dielectric surface inhibits deposition of the molybdenum layer atop the dielectric surface, wherein contacting the metal surface with molybdenum hexacarbonyl is performed at a first temperature of 150 degrees Celsius or less to thermally decompose the molybdenum hexacarbonyl.

In some embodiments, the present disclosure relates to a non-transitory computer readable medium having instructions stored thereon that, when executed, cause a process chamber to perform a method of selectively depositing a layer atop a substrate having a metal surface and a dielectric surface including: contacting a substrate comprising a metal surface and a dielectric layer atop the metal surface with molybdenum hexacarbonyl to selectively deposit a molybdenum layer atop the metal surface of the substrate, wherein the dielectric layer comprises a feature disposed atop the metal surface, and wherein the feature has a top and a bottom and the bottom of the feature is in fluid communication with the metal surface, wherein contacting the substrate with molybdenum hexacarbonyl is performed at a first temperature of 150 degrees Celsius or less to thermally decompose the molybdenum hexacarbonyl.

In some embodiments, the present disclosure relates to a non-transitory computer readable medium having instructions stored thereon that, when executed, cause a process chamber to perform a method of selectively depositing a layer atop a substrate having a metal surface and a dielectric surface including: contacting a substrate comprising a metal surface and a dielectric surface comprising a feature in fluid communication with the metal surface with molybdenum hexacarbonyl to form a molybdenum layer atop the metal surface of the substrate, and within the feature, wherein the molybdenum hexacarbonyl is selective towards the metal surface, wherein contacting the substrate with molybdenum hexacarbonyl is performed at a first temperature of 150 degrees Celsius or less to thermally decompose the molybdenum hexacarbonyl.

While the foregoing is directed to embodiments of the present disclosure, other and further embodiments of the disclosure may be devised without departing from the basic scope thereof.

1. A method of selectively depositing a layer atop a substrate having a metal surface and a dielectric surface, comprising:
contacting the metal surface with molybdenum hexacarbonyl to selectively deposit a molybdenum layer atop the metal surface of the substrate, wherein the dielectric surface inhibits deposition of the molybdenum layer atop the dielectric surface, wherein contacting the metal surface with molybdenum hexacarbonyl is performed at a first temperature of 150 degrees Celsius or less to thermally decompose the molybdenum hexacarbonyl.

2. The method of claim 1, wherein contacting the metal surface with molybdenum hexacarbonyl is performed at a first temperature of about 105 to about 125 degrees Celsius.

3. The method of claim 1, further comprising pre-treating the metal surface to form an exposed metal surface.

4. The method of claim 1, further comprising contacting the metal surface with one or more metal halides to form an exposed metal surface.

5. The method of claim 1, wherein contacting the metal surface with molybdenum hexacarbonyl is performed at a pressure in an amount of 1 to 15 Torr.

6. The method of claim 1, wherein contacting the metal surface with molybdenum hexacarbonyl is performed for 2 to 20 minutes.

7. The method of claim 1, wherein the molybdenum hexacarbonyl is a vapor or gas.

8. The method of claim 1, wherein the contacting the metal surface with molybdenum hexacarbonyl is performed in an oxygen-free chamber or under vacuum.

9. The method of claim 1, wherein contacting the metal surface with molybdenum hexacarbonyl to selectively deposit a molybdenum layer atop the metal surface of the substrate comprises exposing the substrate to a gas or vapor comprising molybdenum hexacarbonyl, and heating the gas or vapor to decompose the molybdenum hexacarbonyl.

10. The method of claim 1, wherein contacting the metal surface with molybdenum hexacarbonyl is performed wherein a temperature of the substrate is at a temperature of about 105 to about 125 degrees Celsius.

11. The method of claim 1, wherein the metal surface is copper (Cu), cobalt (Co), tungsten (W), niobium (Nb), ruthenium (Ru), aluminum (Al), titanium (Ti), nickel (Ni), vanadium (V), zirconium (Zr), Iron (Fe), or combinations thereof.

12. A method of selectively depositing a layer atop a substrate having a metal surface and a dielectric layer, comprising:
contacting a substrate comprising a metal surface and a dielectric layer atop the metal surface with molybdenum hexacarbonyl to selectively deposit a molybdenum layer atop the metal surface of the substrate, wherein the dielectric layer comprises a feature disposed atop the metal surface, and wherein the feature has a top and a bottom and the bottom of the feature is in fluid communication with the metal surface, wherein contacting the substrate with molybdenum hexacarbonyl is performed at a first temperature of 150 degrees Celsius or less to thermally decompose the molybdenum hexacarbonyl.

13. The method of claim 12, wherein contacting the substrate comprising a metal surface and a dielectric surface atop the metal surface with molybdenum hexacarbonyl fills the feature from the bottom of the feature to the top of the feature.

14. The method of claim 12, wherein the contacting the metal surface with molybdenum hexacarbonyl is performed at a first temperature of about 105 to about 125 degrees Celsius.

15. The method of claim 12, wherein contacting the metal surface with molybdenum hexacarbonyl is performed at a pressure in an amount of 1 to 15 Torr.

16. The method of claim 12, wherein contacting the metal surface with molybdenum hexacarbonyl is performed for 2 to 20 minutes.

17. A method of depositing a layer atop a substrate having a metal surface and a dielectric surface, comprising:
contacting a substrate comprising a metal surface and a dielectric surface comprising a feature in fluid communication with the metal surface with molybdenum hexacarbonyl to form a molybdenum layer atop the metal surface of the substrate, and within the feature, wherein the molybdenum hexacarbonyl is selective towards the metal surface, wherein contacting the substrate with molybdenum hexacarbonyl is performed at a first temperature of 150 degrees Celsius or less to thermally decompose the molybdenum hexacarbonyl.

18. The method of claim 17, further comprising filling the feature from a bottom to a top with molybdenum.

19. The method of claim 17, further comprising depositing one or more additional metal layers atop the molybdenum layer and within the feature.

20. The method of claim 19, wherein the one or more additional metal layers comprise copper (Cu), cobalt (Co), tungsten (W), niobium (Nb), ruthenium (Ru), and combinations thereof.
